(19) United States
(12) Patent Application Publication
(10) Pub. No.: US 2014/0318710 A1
(43) Pub. Date: Oct. 30, 2014

(54) APPARATUS FOR GENERATING PLASMA USING ELECTROMAGNETIC FIELD APPLICATOR AND APPARATUS FOR TREATING SUBSTRATE COMPRISING THE SAME

(71) Applicant: PSK INC., Gyeonggi-do (KR)

(72) Inventors: Hee Sun CHAE, Hwaseong-si (KR); Jeonghee CHO, Hwaseong-si (KR); Jong Sik LEE, Hwaseong-si (KR); Han Saem LEE, Hwaseong-si (KR); Hyun Jun KIM, Hwaseong-si (KR)

(73) Assignee: PSK INC., Gyeonggi-do (KR)

(21) Appl. No.: 13/946,197

(22) Filed: Jul. 19, 2013

(30) Foreign Application Priority Data
Apr. 25, 2013 (KR) 10-2013-0045881

(51) Int. Cl. H01J 37/32

(52) U.S. Cl. CPC H01J 37/32183; H01J 37/32357; H01J 2237/327
USPC 156/345.35; 315/39.51

(57) ABSTRACT

A plasma generating apparatus is provided which includes an RF power which provides an RF signal; a plasma chamber which generates a plasma using the RF signal; a plurality of isolation loops which are formed along a circumference of the plasma chamber; and a plurality of electromagnetic applicators which are respectively coupled with the isolation loops and applies an electromagnetic field to the plasma chamber in response to the RF signal, wherein impedance values of the electromagnetic applicators increase according to an increase in a distance from an input terminal.

### CROSS-REFERENCE TO RELATED APPLICATIONS

This U.S. non-provisional patent application claims priority under 35 U.S.C. §119 of Korean Patent Application No. 10-2013-0045881, filed on Apr. 25, 2013, the entire contents of which are hereby incorporated by reference.

### BACKGROUND OF THE INVENTION

The inventive concepts described herein relate to plasma generating apparatus and a substrate treating apparatus including the same.

A process for treating a substrate using plasma may be included in a process for fabricating a semiconductor, a display, a solar cell, and so on. For example, in a semiconductor fabricating process, an ashing apparatus used for ashing or an etching apparatus used for a dry process may include a chamber for generating plasma, and etching or ashing on a substrate may be performed using the plasma.

In the substrate processing device, an electromagnetic field may be induced within the chamber by supplying a time-variable current to a coil installed at the chamber, and plasma may be generated from a gas supplied to the chamber using the induced electromagnetic field.

As an area of a substrate to be treated grows, generation of uniform plasma in the chamber may be required to improve the yield of process. However, in a plasma apparatus with a single induction coil structure, a voltage of an input terminal of a coil may be higher than that of a ground terminal. This may cause such a problem that plasma is irregularly generated within the chamber.

### SUMMARY OF THE INVENTION

One object of the inventive concept is directed to provide a plasma generating apparatus capable of uniformly generating plasma in a chamber and a substrate treating apparatus including the same.

Another object of the inventive concept is directed to provide a plasma generating apparatus capable of improving the yield of process when a large-scaled substrate is treated and a substrate treating apparatus including the same.

One aspect of embodiments of the inventive concept is directed to provide a plasma generating apparatus which comprises an RF power which provides an RF signal; a plasma chamber which generates a plasma using the RF signal; a plurality of isolation loops which are formed along a circumference of the plasma chamber; and a plurality of electromagnetic applicators which are respectively coupled with the isolation loops and applies an electromagnetic field to the plasma chamber in response to the RF signal, wherein impedance values of the electromagnetic applicators increase according to an increase in a distance from an input terminal.

In example embodiments, each of the electromagnetic applicators comprises a first magnetic material which surrounds a part of a corresponding isolation loop; a second magnetic material which surrounds the remaining of the corresponding isolation loop; and a coil which winds the first magnetic material and the second magnetic material.

In example embodiments, the first magnetic material comprises a first upper magnetic material for surrounding an upper half of the part of the corresponding isolation loop and a first lower magnetic material for surrounding a lower half of the part of the corresponding isolation loop, and the second magnetic material comprises a second upper magnetic material for surrounding an upper half of the remaining of the corresponding isolation loop and a second lower magnetic material for surrounding a lower half of the remaining of the corresponding isolation loop.

In example embodiments, the plurality of electromagnetic applicators is connected in series.

In example embodiments, a part of the plurality of electromagnetic applicators is connected in series to form a first applicator group and the remaining thereof is connected in series to form a second applicator group, the first applicator group being connected in parallel with the second applicator group.

In example embodiments, as the plurality of electromagnetic applicators goes from an input terminal to a ground terminal, a winding number of the coil increases.

In example embodiments, as the plurality of electromagnetic applicators goes from an input terminal to a ground terminal, a distance between the first upper magnetic material and the first lower magnetic material and a distance between the second upper magnetic material and the second lower magnetic material decrease.

In example embodiments, insulation materials are inserted between the first upper magnetic material and the first lower magnetic material and between the second upper magnetic material and the second lower magnetic material decrease, respectively.

In example embodiments, the plurality of electromagnetic applicators includes eight electromagnetic applicators, four electromagnetic applicators of the eight electromagnetic applicators are connected in series to form a first applicator group, the remaining of the eight electromagnetic applicators are connected in series to form a second applicator group, the first applicator group is connected in parallel with the second applicator group, an impedance ratio of the four electromagnetic applicators in the first applicator group is 1:1.5:4:8, and an impedance ratio of the four electromagnetic applicators in the second applicator group is 1:1.5:4:8.

Another aspect of embodiments of the inventive concept is directed to provide a substrate treating apparatus comprising a process unit which provides a space where a substrate to be treated is disposed; a plasma generating unit which generate a plasma to be supplied to the process unit; and a discharge unit which discharges a gas in the process unit and a reaction by-product. The plasma generating unit comprises an RF power which provides an RF signal; a plasma chamber which generates a plasma using the RF signal; a plurality of isolation loops which are formed along a circumference of the plasma chamber; and a plurality of electromagnetic applicators which are respectively coupled with the isolation loops and applies an electromagnetic field to the plasma chamber in response to the RF signal, wherein impedance values of the electromagnetic applicators increase according to an increase in a distance from an input terminal.

In example embodiments, each of the electromagnetic applicators comprises a first magnetic material which surrounds a part of a corresponding isolation loop; a second magnetic material which surrounds the remaining of the corresponding isolation loop; and a coil which winds the first magnetic material and the second magnetic material.

In example embodiments, the first magnetic material comprises a first upper magnetic material for surrounding an upper half of the part of the corresponding isolation loop and a first lower magnetic material for surrounding a lower half of the part of the corresponding isolation loop, and the second magnetic material comprises a second upper magnetic material for surrounding an upper half of the remaining of the corresponding isolation loop and a second lower magnetic material for surrounding a lower half of the remaining of the corresponding isolation loop.

In example embodiments, the plurality of electromagnetic applicators is connected in series.

In example embodiments, a part of the plurality of electromagnetic applicators is connected in series to form a first applicator group and the remaining thereof is connected in series to form a second applicator group, the first applicator group being connected in parallel with the second applicator group.

In example embodiments, as the plurality of electromagnetic applicators goes from an input terminal to a ground terminal, a winding number of the coil increases.

In example embodiments, as the plurality of electromagnetic applicators goes from an input terminal to a ground terminal, a distance between the first upper magnetic material and the first lower magnetic material and a distance between the second upper magnetic material and the second lower magnetic material decrease.

In example embodiments, insulation materials are inserted between the first upper magnetic material and the first lower magnetic material and between the second upper magnetic material and the second lower magnetic material decrease, respectively.

In example embodiments, the plurality of electromagnetic applicators includes eight electromagnetic applicators, four electromagnetic applicators of the eight electromagnetic applicators are connected in series to form a first applicator group, the remaining of the eight electromagnetic applicators are connected in series to form a second applicator group, the first applicator group is connected in parallel with the second applicator group, an impedance ratio of the four electromagnetic applicators in the first applicator group is 1:1.5:4:8, and an impedance ratio of the four electromagnetic applicators in the second applicator group is 1:1.5:4:8.

With embodiments of the inventive concept, it is possible to uniformly generate plasma in a chamber. In particular, it is possible to uniformly generate plasma in a large chamber for treating a large-scaled substrate. Also, the yield of process may be improved when a large-scaled substrate is treated.

### BRIEF DESCRIPTION OF THE DRAWINGS

The above and other objects and features will become apparent from the following description with reference to the following figures, wherein like reference numerals refer to like parts throughout the various figures unless otherwise specified, and wherein

FIG. 1 is a diagram schematically illustrating a substrate treating apparatus according to an embodiment of the inventive concept.

FIG. 2 is a plane view of a plasma generating unit 300 according to an embodiment of the inventive concept.

FIG. 3 is a front view of an electromagnetic applicator according to an embodiment of the inventive concept.

FIG. 4 is a circuit diagram schematically illustrating a plasma generating unit 300 according to an embodiment of the inventive concept.

FIG. 5 is a plane view of a plasma generating unit 300 according to another embodiment of the inventive concept.

FIG. 6 is a circuit diagram schematically illustrating a plasma generating unit 300 according to another embodiment of the inventive concept.

### DETAILED DESCRIPTION OF PREFERRED EMBODIMENTS

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

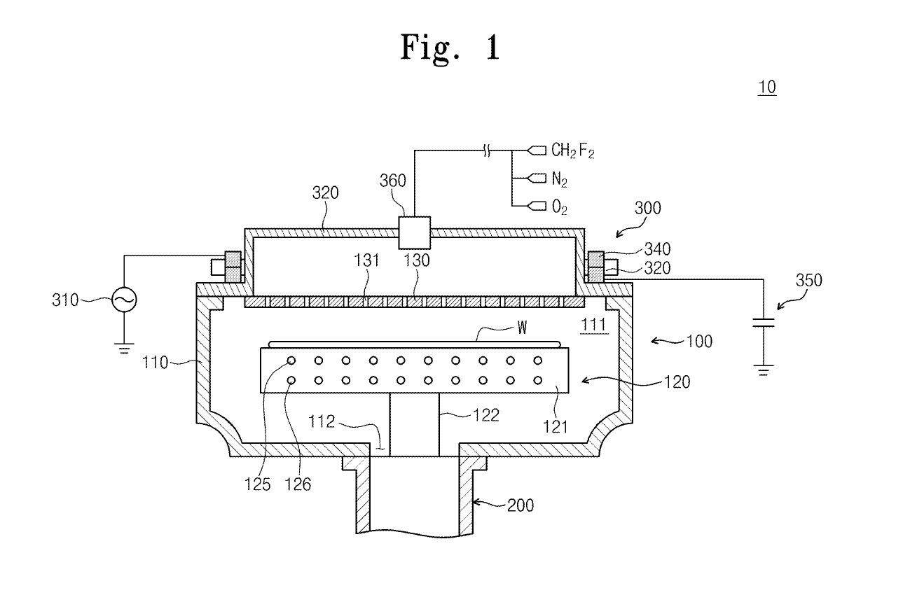

FIG. 1 is a diagram schematically illustrating a substrate treating apparatus according to an embodiment of the inventive concept.

Referring to FIG. 1, a substrate treating apparatus 10 may treat a thin film on substrate W using plasma (e.g., etching or ashing). A thin film for etching or ashing may be a nitride film. In example embodiments, the nitride film may be a silicon nitride film.

The substrate treating apparatus 10 may include a process unit 100, a discharge unit 200, and a plasma generating unit 300. The process unit 100 may provide a space in which an etching or ashing process on the substrate W is performed. The discharge unit 200 may discharge a process gas remaining at the process unit 100 or reaction by-product generated at a substrate treating process, and may maintain a pressure in the process unit 100 by a setting pressure. The plasma generating unit 300 may generate plasma from a process gas supplied from the exterior, and may supply the plasma to the process unit 100.

The process unit 100 may include a process chamber 110, a substrate support unit 120, and a baffle 130. The process chamber 110 may have a treatment space 111 where a substrate treating process is performed. An upper wall of the process chamber 110 may be opened, and opening (not shown) may be formed at a side wall of the process chamber 110. The opening may be used to put or take the substrate W in or out the process chamber 110. The opening may be closed or opened by an open and close member such as a door. The discharge hole 112 may be formed at a bottom surface of the process chamber 110. A discharge hole 112 may be connected with the discharge unit 200, and may provide a path for discharging a gas remaining in the process chamber 110 or a reaction by-product to the exterior.

The substrate support unit 120 may support the substrate W. The substrate support unit 120 may include a susceptor 121 and a support spindle 122. The susceptor 121 may be placed within the treatment space 111, and may have a circular disk shape. The susceptor 121 may be supported by the support spindle 122. The substrate W may be put on an upper surface of the susceptor 121. An electrode (not shown) may be provided in the susceptor 121. The electrode may be connected with an external power, and may generate static electricity using an applied power. The substrate W may be fixed to the susceptor 121 by the static electricity. A heating member 125 may be provided in the susceptor 121. In example embodiments, the heating member 125 may be formed of a heating coil. Also, a cooling member 126 may be provided in the susceptor 121. The cooling member 126 may be formed of a cooling pipe through which cooling water flows. The heating member 125 may heat the substrate W by a predetermined temperature. The cooling member 126 may cool the substrate W forcibly. The substrate W treated at a process may be cooled to have a room temperature or a temperature required for progress of a next process.

The baffle 130 may be put on an upper portion of the susceptor 121. Holes 131 may be formed at the baffle 130. The holes 131 may be through holes formed to penetrate the baffle 130, and may be uniformly distributed all over the baffle 130.

The plasma generating unit 300 may be located on an upper portion of the process chamber 110. The plasma generating unit 300 may generate plasma through discharge of a source gas, and supply the plasma to the treatment space 111. The plasma generating unit 300 may include an RF power 310, a plasma chamber 320, an isolation loop, and an electromagnetic applicator 340. Also, the plasma generating unit 300 may further include a source gas supplying unit 360.

The plasma chamber 320 may be located on an upper portion of the process chamber 110, and may be connected with the process chamber 110. A top of the plasma chamber 320 can be connected with the source gas supplying unit 360. The source gas may be supplied to a discharge space in the plasma chamber 320. The source gas may include CH2F2 (Difluoromethane), N2, and O2. The source gas may further include CF4 (Tetrafluoromethane), selectively.

The electromagnetic applicator 340 may be installed at a side wall of a chamber 320 through the isolation loop 330. The RF power 310 may supply a high-frequency current to the electromagnetic applicator 340. The high-frequency current supplied to the electromagnetic applicator 340 may be applied to the discharge space. An electric field induced by the high-frequency current may be formed in the discharge space, and a source gas in the discharge space may obtain an energy needed for ionization from the electric field so as to be changed into a plasma state. A ground terminal of the electromagnetic applicator 340 may be connected with a capacitor 350 or directly grounded without connection with a capacitor.

A structure of the plasma generating unit 300 may not be limited to this disclosure. For example, various structures may be used to generate plasma from a source gas.

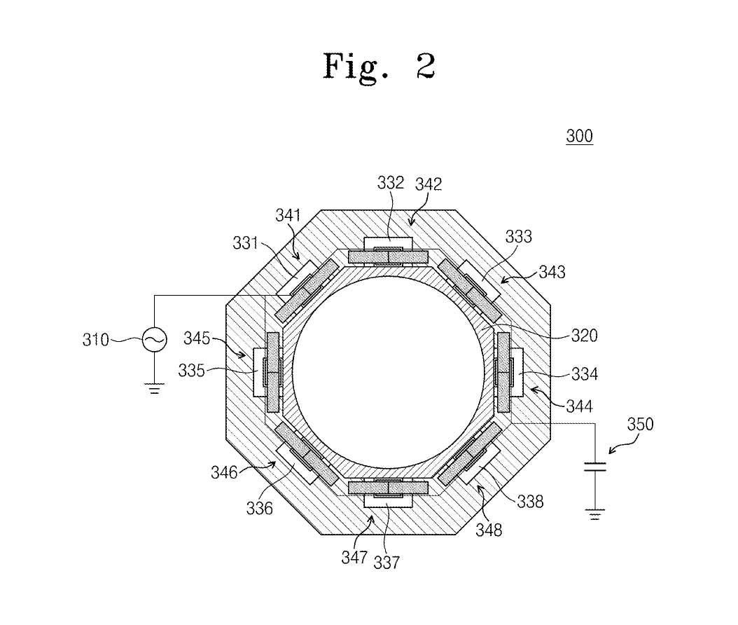

FIG. 2 is a plane view of a plasma generating unit 300 according to an embodiment of the inventive concept.

As illustrated in FIG. 2, a plasma generating unit 300 may include an RF power 310, a plasma chamber 320, a plurality of isolation loops 331 to 338, and a plurality of electromagnetic applicators 341 to 348.

The RF power 310 may provide an RF signal. The plasma chamber 320 may generate plasma using the RF signal. The isolation loops 331 to 338 may be formed along a circumference of the plasma chamber 320. The electromagnetic applicators 341 to 348 may be coupled with the isolation loops 331 to 338, and may apply an electromagnetic field to the plasma chamber 320 in response to the RF signal.

In example embodiments, the RF power 310 may generate the RF signal to output it to the electromagnetic applicators 341 to 348. The power 310 may transfer a high-frequency power to the plasma chamber 320 through the RF signal. In example embodiments, the RF power 310 may generate and output a sine wave RF signal. However, the inventive concept is not limited thereto. For example, the RF signal may have various waveforms such as a square wave, a chopping wave, a saw tooth wave, a pulse wave, and so on.

The plasma chamber 320 may generate plasma from an input gas. In example embodiments, the plasma chamber 320 may convert a gas injected into a chamber into plasma using a high-frequency power transferred through the RF signal.

In example embodiments, an outer wall of the plasma chamber 320 may have a polygonal cross section. For example, as illustrated in FIG. 2, an outer wall of the plasma chamber 320 may have an octagonal cross section. However, the inventive concept is not limited thereto.

With the inventive concept, a cross-sectional shape of the outer wall of the plasma chamber 320 may be decided according to the number of isolation loops or electromagnetic applicators installed at a chamber. For example, in the event that a cross section of an outer wall of the plasma chamber 320 is polygonal, the number of sides of the polygon may be equal to the numbers of isolation loops or electromagnetic applicators.

As illustrated in FIG. 2, an inner wall of the plasma chamber 320 may have a circular cross section. However, the inventive concept is not limited thereto.

The isolation loops 331 to 338 may be formed along a circumference of the plasma chamber 320. For example, as illustrated in FIG. 2, the isolation loops 331 to 338 may be regularly installed along an outer wall of the plasma chamber 320 to be spaced apart from each other. In FIG. 2, there is illustrated an example in which the plasma generating unit 300 includes eight isolation loops 331 to 338. However, the number of isolation loops may be changed according to embodiments.

The isolation loops 331 to 338 may be made up of an insulator. The isolation loops 331 to 338 may be made up of quartz or ceramic. However, the inventive concept is not limited thereto.

The isolation loops 331 to 338 may form a closed loop together with an outer wall of the plasma chamber 320. For example, as illustrated in FIG. 2, the isolation loops 331 to 338 may be formed to have a ‘ [symbol] ’ or ‘U’ shape. The isolation loops 331 to 338 may form a closed loop when installed at an outer wall of the plasma chamber 320.

The electromagnetic applicator 341 to 348 may be installed in the isolation loops 331 to 338, respectively.

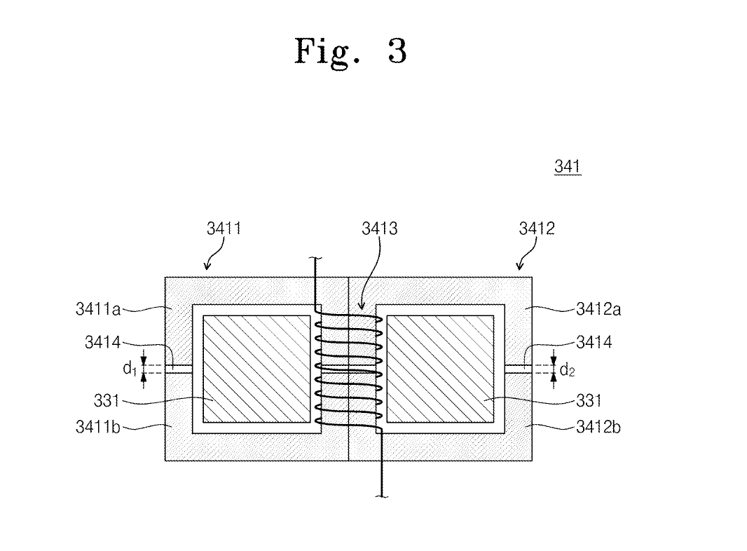

FIG. 3 is a front view of an electromagnetic applicator according to an embodiment of the inventive concept.

As illustrated in FIG. 3, an electromagnetic applicator 341 may include a first magnetic material 3411, a second magnetic material 3412, and a coil 3413. The first magnetic material 3411 may surround a part of an isolation loop 331. The second magnetic material 3412 may surround the other of the isolation loop 331. The coil 3413 may be wound at the first magnetic material 3411 and the second magnetic material 3412.

In example embodiments, the first magnetic material 3411 and the second magnetic material 3412 may be installed to be adjacent to each other. For example, as illustrated in FIG. 3, the first magnetic material 3411 and the second magnetic material 3412 may be installed to get in contact with each other. However, the first magnetic material 3411 and the second magnetic material 3412 can be installed to be spaced apart from each other.

With the inventive concept, at least one of the first magnetic material 3411 and the second magnetic material 3412 may be formed of at least two components assembled.

For example, as illustrated in FIG. 3, the first magnetic material 3411 may include a first upper magnetic material 3411a surrounding an upper half of a part of the isolation loop 331 and a first lower magnetic material 3411b surrounding a lower half of the part of the isolation loop 331. Also, the second magnetic material 3412 may include a second upper magnetic material 3412a surrounding an upper half of the remaining of the isolation loop 331 and a second lower magnetic material 3412b surrounding a lower half of the remaining of the isolation loop 331.

As described above, the first magnetic material 3411 and the second magnetic material 3412 may be formed of at least two components assembled. However, each of all of the first magnetic material 3411 and the second magnetic material 3412 can be formed of a body.

Returning to FIG. 2, electromagnetic applicators 341 to 348 may apply an electromagnetic field to a plasma chamber 320 in response to an RF signal. The RF signal output from an RF power 310 may be applied to the coil 3413 of the electromagnetic applicator 341, and the electromagnetic applicator 341 may induce an electromagnetic field using a time-variable current flowing along the coil 3413 to apply it to the plasma chamber 320.

With the inventive concept, a part of a plurality of electromagnetic applicators may be connected in series and form a first applicator group. The remaining of the plurality of electromagnetic applicators may be connected in series and form a second applicator group. The first applicator group and the second applicator group may be connected in parallel.

For example, as illustrated in FIG. 2, the plasma generating unit 300 may include eight electromagnetic applicators 341 to 348. Four electromagnetic applicators 341 to 344 of the eight electromagnetic applicators 341 to 348 may be connected in series and form the first applicator group. The remaining electromagnetic applicators 345 to 348 may be connected in series and form the second applicator group. Also, as illustrated in FIG. 2, the first applicator group and the second applicator group may be connected in parallel.

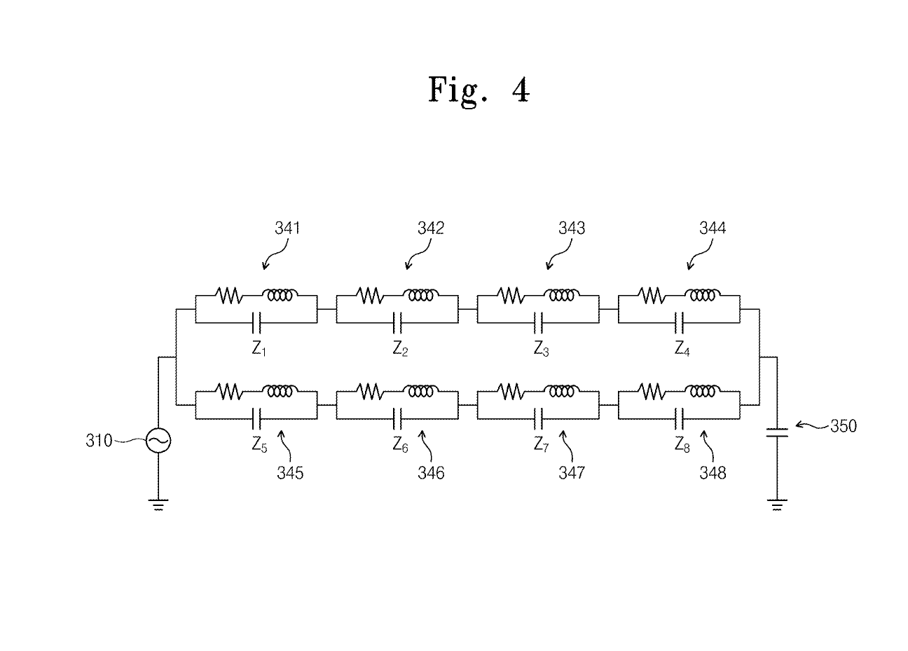

FIG. 4 is a circuit diagram schematically illustrating a plasma generating unit 300 according to an embodiment of the inventive concept.

As illustrated in FIG. 4, each of electromagnetic applicators 341 to 348 may be illustrated by a resistor, an inductor, and a capacitor. Four electromagnetic applicators 341 to 344 in a first applicator group may be connected in series, and four electromagnetic applicators 345 to 348 in a second applicator group may be connected in series. The first applicator group and the second applicator group may be connected in series.

With the inventive concept, as the electromagnetic applicators 341 to 348 go from an input terminal to a ground terminal, impedance values of the electromagnetic applicators 341 to 348 may increase.

For example, referring to FIG. 4, in the first applicator group, an impedance value Z₁ of a first electromagnetic applicator 341 closest to the input terminal may be smallest, and an impedance value Z₄ of a fourth electromagnetic applicator 344 far away from the input terminal may be largest. That is, Z₁<Z₂<Z₃<Z₄.

Also, in a second applicator group, an impedance value Z₅ of a fifth electromagnetic applicator 345 closest to the input terminal may be smallest, and an impedance value Z₈ of an eighth electromagnetic applicator 348 far away from the input terminal may be largest. That is, Z₅<Z₆<Z₇<Z₈.

With the inventive concept, in the first and second applicator groups connected in parallel, electromagnetic applicators existing at corresponding locations may have the same impedance value.

For example, referring to FIG. 4, in the first and second applicator groups connected in parallel, the impedance value Z₁ of the first electromagnetic applicator 341 may be equal to the impedance value Z₅ of the fifth electromagnetic applicator 345. The impedance value Z₂ of the second electromagnetic applicator 342 may be equal to the impedance value Z₆ of the sixth electromagnetic applicator 346. The impedance value Z₃ of the third electromagnetic applicator 343 may be equal to the impedance value Z₇ of the seventh electromagnetic applicator 347. The impedance value Z₄ of the fourth electromagnetic applicator 344 may be equal to the impedance value Z₈ of the eighth electromagnetic applicator 348.

With the inventive concept, as the electromagnetic applicators go from an input terminal to a ground terminal, a winding number of a coil 3413 may increase. As a winding number of the coil 3413 increases, inductance of the coil 3413 may increase. Thus, as the electromagnetic applicators go from an input terminal to a ground terminal, impedance values of the electromagnetic applicators may increase.

Referring to FIG. 2, for example, in the first applicator group, winding numbers may increase in this order of the first to fourth electromagnetic applicators 341 to 344.

Likewise, referring to FIG. 2, in the second applicator group, winding numbers may increase in this order of the first to fourth electromagnetic applicators 345 to 348.

Also, electromagnetic applicators placed at the same location in the first and second applicator groups connected in parallel may have the same winding number. For example, the winding number of the first electromagnetic applicator 341 may be equal to the winding number of the fifth electromagnetic applicator 345. The winding number of the second electromagnetic applicator 342 may be equal to the winding number of the sixth electromagnetic applicator 346. The winding number of the third electromagnetic applicator 343 may be equal to the winding number of the seventh electromagnetic applicator 347. The winding number of the fourth electromagnetic applicator 344 may be equal to the winding number of the eighth electromagnetic applicator 348.

With another embodiment of the inventive concept, as the electromagnetic applicators go from an input terminal to a ground terminal, a distance d1 between a first upper magnetic material 3411a and a first lower magnetic material 3411b and a distance d2 between a second upper magnetic material 3412a and a second lower magnetic material 3412b may decrease.

As distances d1 and d2 between upper magnetic materials and lower magnetic materials increase, a coupling coefficient between a magnetic material and a coil may decrease. This may mean that inductance decreases. As inductance decreases, impedance of an electromagnetic applicator may decrease. Thus, as the electromagnetic applicators go from an input terminal to a ground terminal, impedance values of the electromagnetic applicators may increase.

Referring to FIG. 2, for example, in the first applicator group, distances d1 and d2 may decrease in this order of the first to fourth electromagnetic applicators 341 to 344.

Likewise, referring to FIG. 2, in the second applicator group, distances d1 and d2 may decrease in this order of the first to fourth electromagnetic applicators 345 to 348.

Also, distances d1 and d2 of electromagnetic applicators placed at the same location in the first and second applicator groups connected in parallel may be equal to each other. For example, the distances d1 and d2 of the first electromagnetic applicator 341 may be equal to the distances d1 and d2 of the fifth electromagnetic applicator 345. The distances d1 and d2 of the second electromagnetic applicator 342 may be equal to the distances d1 and d2 of the sixth electromagnetic applicator 346. The distances d1 and d2 of the third electromagnetic applicator 343 may be equal to the distances d1 and d2 of the seventh electromagnetic applicator 347. The distances d1 and d2 of the fourth electromagnetic applicator 344 may be equal to the distances d1 and d2 of the eighth electromagnetic applicator 348.

As described above, as the electromagnetic applicators go from an input terminal to a ground terminal, winding numbers may increase or distances between magnetic materials may decrease, so that impedance values of the electromagnetic applicators increase. In some embodiments, as the electromagnetic applicators go from an input terminal to a ground terminal, winding numbers may increase and distances between magnetic materials may decrease. In this case, an impedance value of an electromagnetic applicator may be roughly tuned by a winding number of a coil and finely tuned by a distance between magnetic materials.

In example embodiments, an insulation material can be inserted between magnetic materials of an electromagnetic applicator.

As illustrated in FIG. 3, for example, an electromagnetic applicator may include insulation materials 3413 respectively inserted between a first upper magnetic material 3411a and a first lower magnetic material 3411b and between a second upper magnetic material 3412a and a second lower magnetic material 3412b. The insulation materials 3414 may be a tape formed of an insulation material. In this case, one or more sheets of insulation tapes may be inserted between magnetic materials to adjust distances d1 and d2 between the magnetic materials.

Referring to FIGS. 2 and 4, the plasma generating unit 300 according to an embodiment of the inventive concept may include eight electromagnetic applicators 341 to 348. Four electromagnetic applicators 341 to 344 of the eight electromagnetic applicators 341 to 348 may be connected in series and form the first applicator group. The remaining electromagnetic applicators 345 to 348 may be connected in series and form the second applicator group. An impedance ratio of the electromagnetic applicators 341 to 344 in the first applicator group may be 1:1.5:4:8 and an impedance ratio of the electromagnetic applicators 345 to 348 in the second applicator group may be 1:1.5:4:8. That is, Z₁:Z₂:Z₃:Z₄=Z₅:Z₆:Z₇:Z₈=1:1.5:4:8.

The plasma generating unit 300 illustrated in FIGS. 2 and 4 may include eight electromagnetic applicators 341 to 348. However, the inventive concept is not limited thereto. For example, the number of electromagnetic applicators may be less or more than 8.

Also, the plasma generating unit 300 illustrated in FIGS. 2 and 4 may be configured such that two applicator groups are connected in parallel. However, the number of applicator groups connected in parallel may be less or more than 2. For example, the plasma generating unit 300 may include nine electromagnetic applicators, which are divided into three applicator groups each having three electromagnetic applicators. The three applicator groups may be connected in parallel with one another.

Unlike the above description, electromagnetic applicators can be connected in series.

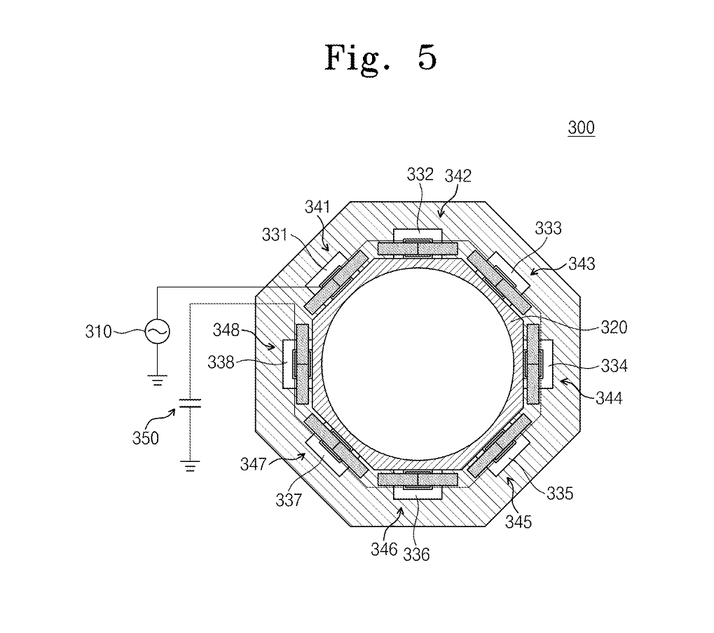

FIG. 5 is a plane view of a plasma generating unit 300 according to another embodiment of the inventive concept.

Referring to FIG. 5, a plasma generating unit 300 may include a plurality of electromagnetic applicators 341 to 348. Unlike an embodiment described in FIG. 2, the electromagnetic applicators 341 to 348 may be connected in series.

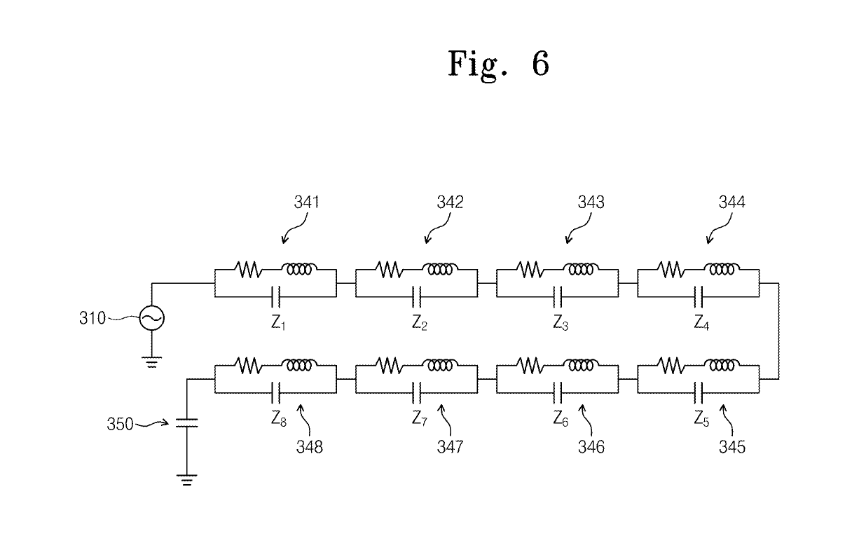

FIG. 6 is a circuit diagram schematically illustrating a plasma generating unit 300 according to another embodiment of the inventive concept.

As illustrated in FIG. 6, a plurality of electromagnetic applicators 341 to 348 may be connected in series. As the electromagnetic applicators 341 to 348 go from an input terminal to a ground terminal, impedance values of the electromagnetic applicators 341 to 348 may increase. In other words, impedance values of the first to eighth electromagnetic applicators may be decided to satisfy a condition of Z₁<Z₂<Z₃<Z₄<Z₅<Z₆<Z₇<Z₈.

There are described a plasma generating apparatus configured such that a plurality of electromagnetic applicators is installed along a circumference of a plasma chamber and impedance values of the electromagnetic applicators increase according to an increase in a distance from an input terminal and a substrate treating apparatus including the same.

With the plasma generating apparatus and the substrate treating apparatus, it is possible to prevent such a phenomenon that plasma is irregularly generated due to voltage unbalance. In particular, the yield of substrate treating process may be improving by uniformly generating plasma in a large chamber for treating a large-scaled substrate.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A plasma generating apparatus, comprising:
an RF power which provides an RF signal;
a plasma chamber which generates plasma using the RF signal;
a plurality of isolation loops which are formed along a circumference of the plasma chamber; and
a plurality of electromagnetic applicators which are respectively coupled with the isolation loops and applies an electromagnetic field to the plasma chamber in response to the RF signal,
wherein impedance values of the electromagnetic applicators increase according to an increase in a distance from an input terminal.

2. The plasma generating apparatus of claim 1, wherein each of the electromagnetic applicators comprises:
a first magnetic material which surrounds a part of a corresponding isolation loop;
a second magnetic material which surrounds the remaining of the corresponding isolation loop; and
a coil which winds the first magnetic material and the second magnetic material.

3. The plasma generating apparatus of claim 2, wherein the first magnetic material comprises a first upper magnetic material for surrounding an upper half of the part of the corresponding isolation loop and a first lower magnetic material for surrounding a lower half of the part of the corresponding isolation loop, and the second magnetic material comprises a second upper magnetic material for surrounding an upper half of the remaining of the corresponding isolation loop and a second lower magnetic material for surrounding a lower half of the remaining of the corresponding isolation loop.

4. The plasma generating apparatus of claim 1, wherein the plurality of electromagnetic applicators is connected in series.

5. The plasma generating apparatus of claim 1, wherein a part of the plurality of electromagnetic applicators is connected in series to form a first applicator group and the remaining thereof is connected in series to form a second applicator group, the first applicator group being connected in parallel with the second applicator group.

6. The plasma generating apparatus of claim 2, wherein as the plurality of electromagnetic applicators goes from an input terminal to a ground terminal, a winding number of the coil increases.

7. The plasma generating apparatus of claim 3, wherein as the plurality of electromagnetic applicators goes from an input terminal to a ground terminal, a distance between the first upper magnetic material and the first lower magnetic material and a distance between the second upper magnetic material and the second lower magnetic material decrease.

8. The plasma generating apparatus of claim 7, wherein insulation materials are inserted between the first upper magnetic material and the first lower magnetic material and between the second upper magnetic material and the second lower magnetic material decrease, respectively.

9. The plasma generating apparatus of claim 1, wherein the plurality of electromagnetic applicators includes eight electromagnetic applicators, four electromagnetic applicators of the eight electromagnetic applicators are connected in series to form a first applicator group, the remaining of the eight electromagnetic applicators are connected in series to form a second applicator group, the first applicator group is connected in parallel with the second applicator group, an impedance ratio of the four electromagnetic applicators in the first applicator group is 1:1.5:4:8, and an impedance ratio of the four electromagnetic applicators in the second applicator group is 1:1.5:4:8.

10. A substrate treating apparatus, comprising:
a process unit which provides a space where a substrate to be treated is disposed;
a plasma generating unit which generate a plasma to be supplied to the process unit; and
a discharge unit which discharges a gas in the process unit and a reaction by-product,
wherein the plasma generating unit comprises:
an RF power which provides an RF signal;
a plasma chamber which generates plasma using the RF signal;
a plurality of isolation loops which are formed along a circumference of the plasma chamber; and
a plurality of electromagnetic applicators which are respectively coupled with the isolation loops and applies an electromagnetic field to the plasma chamber in response to the RF signal,
wherein impedance values of the electromagnetic applicators increase according to an increase in a distance from an input terminal.

11. The substrate treating apparatus of claim 10, wherein each of the electromagnetic applicators comprises:
a first magnetic material which surrounds a part of a corresponding isolation loop;
a second magnetic material which surrounds the remaining of the corresponding isolation loop; and
a coil which winds the first magnetic material and the second magnetic material.

12. The substrate treating apparatus of claim 11, wherein the first magnetic material comprises a first upper magnetic material for surrounding an upper half of the part of the corresponding isolation loop and a first lower magnetic material for surrounding a lower half of the part of the corresponding isolation loop, and the second magnetic material comprises a second upper magnetic material for surrounding an upper half of the remaining of the corresponding isolation loop and a second lower magnetic material for surrounding a lower half of the remaining of the corresponding isolation loop.

13. The substrate treating apparatus of claim 10, wherein the plurality of electromagnetic applicators is connected in series.

14. The substrate treating apparatus of claim 10, wherein a part of the plurality of electromagnetic applicators is connected in series to form a first applicator group and the remaining thereof is connected in series to form a second applicator group, the first applicator group being connected in parallel with the second applicator group.

15. The substrate treating apparatus of claim 11, wherein as the plurality of electromagnetic applicators goes from an input terminal to a ground terminal, a winding number of the coil increases.

16. The substrate treating apparatus of claim 12, wherein as the plurality of electromagnetic applicators goes from an input terminal to a ground terminal, a distance between the first upper magnetic material and the first lower magnetic material and a distance between the second upper magnetic material and the second lower magnetic material decrease.

17. The substrate treating apparatus of claim 16, wherein insulation materials are inserted between the first upper magnetic material and the first lower magnetic material and between the second upper magnetic material and the second lower magnetic material decrease, respectively.

18. The substrate treating apparatus of claim 10, wherein the plurality of electromagnetic applicators includes eight electromagnetic applicators, four electromagnetic applicators of the eight electromagnetic applicators are connected in series to form a first applicator group, the remaining of the eight electromagnetic applicators are connected in series to form a second applicator group, the first applicator group is connected in parallel with the second applicator group, an impedance ratio of the four electromagnetic applicators in the first applicator group is 1:1.5:4:8, and an impedance ratio of the four electromagnetic applicators in the second applicator group is 1:1.5:4:8.
